(19) United States
(12) Patent Application Publication
(10) Pub. No.: US 2009/0146223 A1
(43) Pub. Date: Jun. 11, 2009

(54) PROCESS AND METHOD TO LOWER CONTACT RESISTANCE

(75) Inventors: Sameer H. Jain, Beacon, NY (US); Shreesh Narasimha, Beacon, NY (US); Karen A. Nummy, Newburgh, NY (US); Katsunori Onishi, Iizuka (JP); Viorel C. Ontalus, Danbury, CT (US); Jang H. Sim, Fishkill, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/950,574

(22) Filed: Dec. 5, 2007

(51) Int. Cl. H01L 29/94; H01L 21/8236

(52) U.S. Cl. 257/408; 438/278; 257/E21.631; 257/E29.345

(57) ABSTRACT

A method removes the spacers from the sides of a transistor gate stack, and after the spacers are removed, the method implants an additional impurity into surface regions of the substrate not protected by the gate conductor (or alternatively just amorphizes these surface regions, without adding more impurity). The method then performs a laser anneal on the additional impurity (to activate the additional impurity) or amorphized regions (to recrystallize the amorphized regions). After this, permanent spacers are formed on the sidewalls of the gate conductor. Then, the surface regions of the substrate not protected by the gate conductor and the permanent spacers are silicided, to create silicide source/drain regions. This forms the silicide regions in the additional impurity or in the recrystallized amorphized regions to reduce the source/drain resistance by improving the active dopant concentration at the silicon-silicide interface.

### FIELD OF THE INVENTION

The present invention generally relates to integrated circuit structures, and, more particularly, to method and structure for a transistor that has an additional doped (or amorphized) region that extends toward the channel of the transistor further than silicide of source/drain of the transistor does, to reduce the source/drain resistance by improving the active dopant concentration at the silicon-silicide interface.

### BACKGROUND OF THE INVENTION

As integrated circuit devices are made smaller, external resistance of the metal oxide semiconductor (MOS) transistor becomes a significant fraction of the total resistance of the device. The external resistance has two components. One is the resistance associated with the contact region, and the other component is the resistance associated with the extension region. Each of these two components can be as big as 10% of the total device resistance in the on state. Therefore, there exists a need in the art to reduce external contact resistance in order to improve performance of the transistors.

### SUMMARY

Embodiments of the present invention help to reduce the contact resistance by improving the active dopant concentration at the silicon-silicide interface.

A method embodiment of the invention focuses on aspects after the gate stack and source/drain regions are completed. The gate stack and source and drain regions are created by forming a gate conductor over a channel region of the substrate, implanting extension impurity implants in regions of the substrate not protected by the gate conductor, forming spacers on sidewalls of the gate conductor, implanting source and drain impurities in the substrate adjacent the extension impurity implants, and performing a rapid thermal anneal (RTA) to activate the extension impurity implants and the source and drain impurities.

The method herein removes the spacers (which are sometimes referred to herein as “temporary” spacers, because they are not part of the final inventive structure). After the spacers are removed, the method implants an additional impurity into surface regions of the substrate not protected by the gate conductor (or alternatively just amorphizes these surface regions, without adding more impurity). The method then performs a laser anneal (or equivalent milisecond aneal, aka “flash anneal”) on the additional impurity (to activate the additional impurity) or amorphized regions (to recrystallize the amorphized regions and further increase dopant activation, in a solid phase epitaxy or “SPE” process). Thus, because of this process the additional impurity (or recrystallized amorphous) regions comprise structural indicia of previous laser annealing including crystal structures that are unique to the rapid and very localized thermal action that occurs during laser annealing. After this, permanent spacers are formed on the sidewalls of the gate conductor. Then, the surface regions of the substrate not protected by the gate conductor and the permanent spacers are silicided, to create silicide source/drain regions. This silicide formation process forms the silicide regions in the additional impurity or in the recrystallized amorphized regions.

This process produces a structure that comprises the gate conductor over the channel region of the substrate. Extension impurity implants are positioned in regions of the substrate adjacent the channel region and source and drain implants are positioned in the substrate adjacent the extension impurity implants. The additional impurity or recrystallized amorphous regions are positioned in the surface regions of the substrate not protected by the gate conductor. The permanent spacers are on the sidewalls of the gate conductor and the silicide regions are positioned in the surface regions of the substrate not protected by the gate conductor and the spacers.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a flow diagram illustrating a preferred method of an embodiment of the invention;

FIG. 2 is a cross-sectional manufacturing stage schematic diagram of a transistor according to embodiments herein;

FIG. 3 is a cross-sectional manufacturing stage schematic diagram of a transistor according to embodiments herein;

FIG. 4 is a cross-sectional manufacturing stage schematic diagram of a transistor according to embodiments herein; and

FIG. 5 is a cross-sectional manufacturing stage schematic diagram of a transistor according to embodiments herein.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, the external resistance of small transistors has two components. One is the resistance associated with the contact region, and the other component is the resistance associated with the extension region. Each of these two components can be as large as 10% of the total device resistance in the on state. The embodiments herein help to reduce the contact resistance by improving the active dopant concentration at the silicon-silicide interface.

Traditional methods implant dopants and activate them through a rapid thermal anneal (RTA) process. The maximum active concentration that can be obtained through this method is limited by the solid solubility of the dopants at the highest anneal temperature. This anneal process defines the lower limit to the contact resistance that can be obtained for silicided source and drain regions of a transistor. For field effect transistors (FETs) a sizeable portion of contact resistance comes from the leading edge (sidewall) of the silicide (where the silicide meets the doped silicon). For example, in some situations up to 70% of the current transfers from the silicon into the silicide near the tip of the silicide. Thus, efforts to reduce contact resistance herein improve the activation at the tip of the silicide.

More specifically, to improve contact resistance, embodiments herein increase the active doping level at the leading edge of the silicide (e.g., the silicide-silicon interface). However, it is difficult to increase active doping levels using conventional processing methods. For example, due to the nitride that is etched during the pre-cleaning process performed before silicide formation, and the silicide growth that can occur under the nitride spacer, the tip of the silicide can be offset from the dopant implant regions by as much as 15-20 nm. This can result in the silicide tip being in a region not doped to the highest possible extent. Further, conventional attempts to simply increase the active concentration of dopants in this region greatly increase the problem of short channel degradation, as these extra dopants undesirably contaminate the channel region.

In view of these issues, one idea of embodiments herein is to implant dopants into the region where the tip of the silicide will finally sit, without creating short channel degradation. With embodiments herein short channel effects are avoided because the additional dopants are implanted after the RTA, and because a laser anneal (LSA) is used to activate the dopants. The LSA results in very good activation, but does not diffuse the dopants into the channel region because of the short thermal budget of the laser anneal.

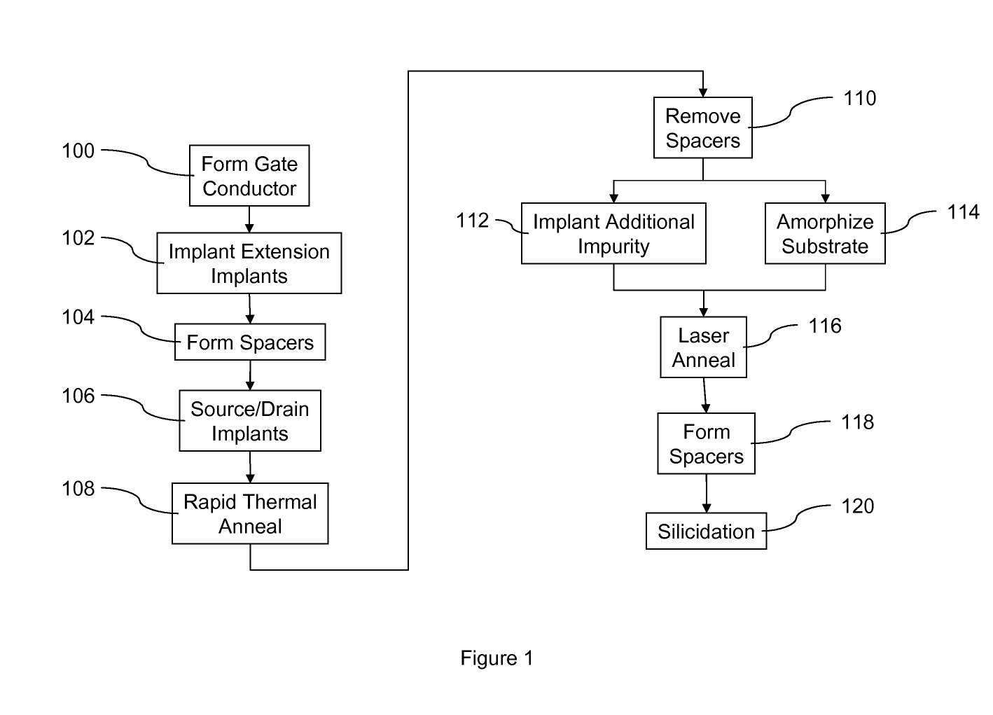

FIG. 1 is a flowchart illustrating a method embodiment of the invention. While the embodiments herein address aspects after the gate stack and source/drain regions are completed, such processes are illustrated in FIG. 1 for completeness. The gate stack and source and drain regions are created by forming a gate conductor over a channel region of the substrate (item 100), implanting extension impurities in regions of the substrate not protected by the gate conductor (item 102), forming spacers on sidewalls of the gate conductor (item 104), implanting source and drain impurities in the substrate adjacent the extension impurities (item 106), and performing a rapid thermal anneal (RTA) to activate the extension implants and the source and drain implants (item 108).

The processing discussed in FIG. 1 involves techniques that are well-known to those ordinarily skilled in the art, although the steps taken to achieve the inventive structure are not well-known. For example, while it is known how to implant impurities, it is not known to implant impurities after removing the gate sidewall spacers to create the unique implant that is discussed in this disclosure. Since such techniques are well-known, they are not discussed in detail herein. One ordinarily skilled in the art would understand that many different methods of deposition (chemical vapor deposition (CVD), plasma vapor deposition (PVD), etc.) and patterning (etching, photolithography, etc.) and other feature formation techniques (damascene, polishing, etc.) could be used with a number of different materials (silicon, polysilicon, oxides, doping agents, etc.) to form the structures that are described in FIG. 1, and that the embodiments herein are applicable to all such techniques, whether now known or developed in the future. As some concrete examples, U.S. Pat. Nos. 7,176,116, and 6,887,762 (which are fully incorporated herein by reference) disclose a few known techniques for transistor devices.

As shown in item 110, the method herein removes the spacers formed in item 104 (which are sometimes referred to herein as “temporary” spacers, because they are not part of the final inventive structure). After the spacers are removed in item 110, the method implants an additional impurity into surface regions of the substrate not protected by the gate conductor in item 112 (or alternatively just amorphizes these surface regions, without adding more impurity in item 114). The additional impurity has the same polarity (N-type or P-type) as the source and drain regions and can, in some embodiments, comprise the same doping species.

The implant dopants are implanted at a low enough energy level to reach the eventual position of where the tip of the silicide will be, but not so far as to cause short channel effects. The actual energy level used will vary from application to application, depending upon the materials being utilized and the size of the structure. For example, implant/amorphization depths of 20 nm (at 1e20 concentration) should be able to improve the dopant concentration at the silicide tip without going too deep into the silicon. Thus, in one example, the additional impurity is implanted (or the substrate is amorphized) to a depth into the surface regions of less than approximately 20 nm from a top surface of the substrate.

The amorphizing implantation species may be Si, Ge, As, Xe, Ar, Sb, P or other ions to amorphize the target silicon substrate location(s) to the appropriate depth. This processing can be accomplished with the aid of a mask. Examples of some possible amorphizing conditions, where Ge or As are used as amorphizing atoms, are implant energy of about 10-60 KeV with a dose of about 3E13-4E15 cm². Details regarding amorphizing implants can be see in U.S. Patent Publication 2007/0138267, the complete disclosure of which is incorporated herein by reference.

The method then performs a laser anneal in item 116 on the additional impurity (to activate the additional impurity) or amorphized regions (to recrystallize the amorphized regions). The annealing comprises heating the amorphous or implanted region to an annealing temperature above the recrystallization temperature of the material, but below its melting point for a very short time (e.g., less than 100 milliseconds). Ultrafast annealing techniques that can be used in some embodiments are laser annealing and flash annealing, with a millisecond-scale characteristic anneal time (e.g., from about 5 milliseconds to about 50 microseconds).

Because of the processing in item 116, the additional impurity (or recrystallized amorphous) regions comprise structural indicia of the laser annealing including crystal structures that are unique to the rapid and very localized thermal action that occurs during laser annealing. After this, permanent spacers are formed on the sidewalls of the gate conductor in item 118. These can be of the same material and same size as the original spacers, or can be of different sizes and materials. Then, the surface regions of the substrate not protected by the gate conductor and the permanent spacers are silicided in item 120, to create silicided source/drain regions. This forms the silicide regions in the additional impurity regions (or in the recrystallized amorphized regions).

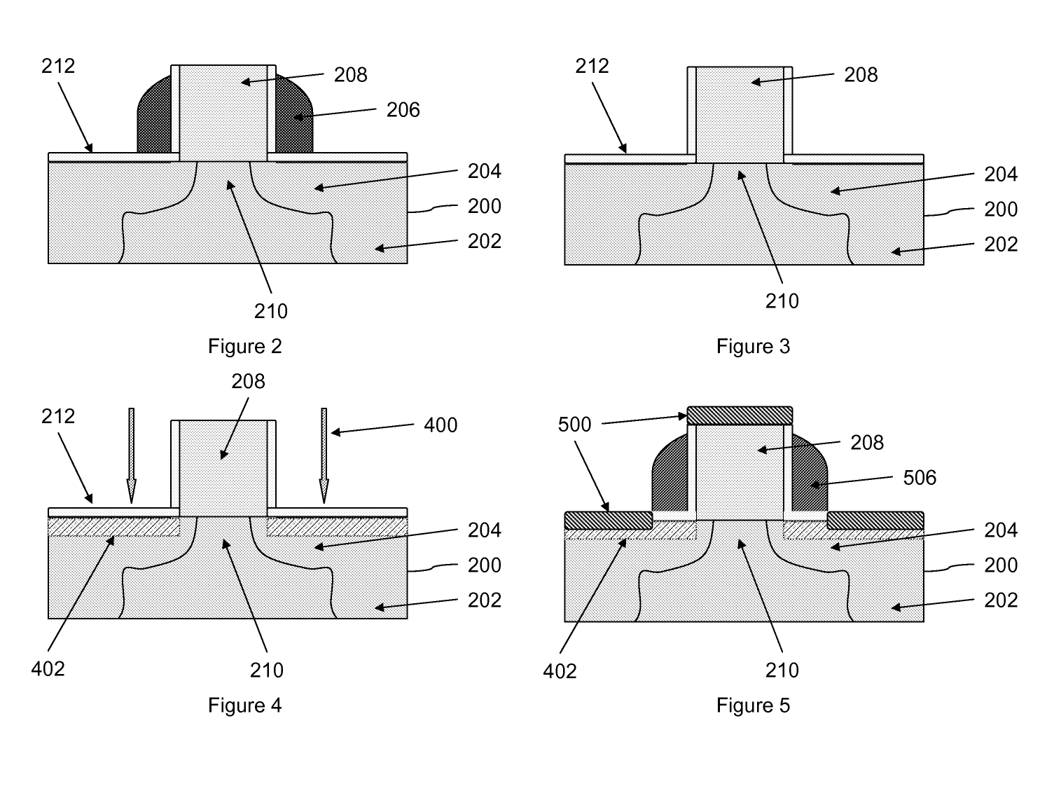

This process is also illustrated in different cross-sectional manufacturing stage schematic diagrams of a transistor in FIGS. 2-5. More specifically, FIG. 2 illustrates the structure through processing up to item 108 in FIG. 1. Thus, FIG. 2 illustrates the gate conductor 208 over the channel region 210 of the substrate 200, and an overlying oxide layer 212. Source and drain extension implants 204 are positioned in regions of the substrate 200 adjacent the channel region 210 and source and drain implants 202 are positioned in the substrate 204 adjacent the extension implants 204. The source and drain implants 202 have a side that is aligned with the outer edge of the spacer 206; however, the source and drain extensions 204 have regions that are closer to the channel region 210 and that actually extend beneath the gate conductor 208 somewhat.

In FIG. 3, the spacers are removed 206 leaving the oxide layer 212 to protect the gate conductor 208. Then, FIG. 4 illustrates the processing in items 112, 114, and 116 (the additional impurity implant or the amorphization 402, and the laser anneal 400). FIG. 5 illustrates the formation of the permanent spacers 506 and the silicide regions 500.

As shown in FIG. 5, the additional impurity or recrystallized amorphous regions 402 are positioned in the top (e.g., surface) regions of the substrate 200 that are not protected by the gate conductor 208. The permanent spacers 506 are on the sidewalls of the gate conductor 208 and the silicide regions 500 are positioned in the surface regions of the substrate 200 that are not protected by the gate conductor 208 and the spacers 506.

As also shown in FIG. 5, the silicide regions 500 are positioned within the additional impurity (or recrystallized amorphous) regions 402 and the additional impurity (or recrystallized amorphous) regions 402 extend toward the channel region 210 further than the silicide regions 500 extend toward the channel region 210. Thus, the additional impurity (or recrystallized amorphous) regions 402 extend under the permanent spacers 506 a certain amount, but not as far as the extension implants 204 do, and clearly not far enough to create short channel effects.

Further, as shown in FIG. 5, the extension implants 204 extend deeper from the top surface of the substrate 200 into the interior of the substrate 200 than the additional impurity (or recrystallized amorphous) regions 402 extend into the interior of the substrate 200. For example, the additional impurity can, in one embodiment, be implanted to a depth into the surface regions of less than approximately 20 nm from a top surface of the substrate.

Thus, as shown above, this embodiment uses a method to introduce additional dopant in the source/drain extension regions without causing diffusion beyond the extension regions. Because the additional impurity is not allowed to diffuse into the channel region, the processing herein avoids the degrading short channel effects. By increasing the dopant concentration around the silicide contact, the invention reduces the contact resistance, without causing short channel effects. The embodiments herein include a process targeted for improving contact resistance at the silicon-silicide contact. The processes introduced herein use LSA (or advanced anneal like flash) for lowering contact resistance selectively. The methods herein can perform doping or amorphization of the contact region, followed by fast recrystallization to achieve high activation and high doping concentration in the silicide vicinity (without diffusion and short channel degradation).

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A structure comprising:
a gate conductor over a channel region of a device in a substrate;
extension impurity implants in regions of said substrate adjacent said channel region;
source and drain impurity implants in said substrate adjacent said extension impurity implants;
an additional impurity in surface regions of said substrate not protected by said gate conductor;
spacers on sidewalls of said gate conductor; and
silicide regions in surface regions of said substrate not protected by said gate conductor and said spacers,
wherein said silicide regions are positioned within said additional impurity, and
wherein said additional impurity extends toward said channel region further than said silicide regions extend toward said channel region.

2. The structure according to claim 1, wherein said extension impurity implants extend from a top surface of said substrate deeper into an interior of said substrate than said additional impurity extends into said interior of said substrate.

3. The structure according to claim 1, wherein said additional impurity extends under said spacers.

4. The structure according to claim 1, wherein said additional impurity is implanted to a depth into said surface regions of less than approximately 20 nm from a top surface of said substrate.

5. The structure according to claim 1, wherein a structure of said additional impurity comprises structural indicia of a laser annealing.

6. A structure comprising:
a gate conductor over a channel region of a device in a substrate;
extension impurity implants in regions of said substrate adjacent said channel region;
source and drain impurity implants in said substrate adjacent said extension impurity implants;
recrystallized amorphous regions in surface regions of said substrate not protected by said gate conductor;
spacers on sidewalls of said gate conductor; and
silicide regions in surface regions of said substrate not protected by said gate conductor and said spacers,
wherein said silicide regions are positioned within said recrystallized amorphous regions, and
wherein said recrystallized amorphous regions extend toward said channel region further than said silicide regions extend toward said channel region.

7. The structure according to claim 6, wherein said extension impurity implants extend deeper from a top surface of said substrate into an interior of said substrate than said recrystallized amorphous regions extend into said interior of said substrate.

8. The structure according to claim 6, wherein said recrystallized amorphous regions extend under said spacers.

9. The structure according to claim 6, wherein said recrystallized amorphous regions are formed to a depth into said surface regions of less than approximately 20 nm from a top surface of said substrate.

10. The structure according to claim 6, wherein a structure of said recrystallized amorphous regions comprises structural indicia of a laser annealing.

11. A method comprising:
forming a gate conductor over a channel region of a device in a substrate;
implanting extension impurities in regions of said substrate not protected by said gate conductor;
forming temporary spacers on sidewalls of said gate conductor;
implanting source and drain impurities in said substrate adjacent said extension impurities;
performing a rapid thermal anneal (RTA) to activate said extension impurities and said source and drain impurities;
removing said temporary spacers;
implanting an additional impurity into surface regions of said substrate not protected by said gate conductor;
performing a laser anneal on said additional impurity;
forming permanent spacers on said sidewalls of said gate conductor; and
siliciding said surface regions of said substrate not protected by said gate conductor and said permanent spacers, to create silicide regions, such that said silicide regions are formed in said additional impurity,
wherein said additional impurity extends toward said channel region further than said silicide regions extend toward said channel region.

12. The method according to claim 11, wherein said implanting of said extension impurities and said implanting of said additional impurity are performed such that said extension impurities extend deeper from a top surface of said substrate into an interior of said substrate than said additional impurity extends into said interior of said substrate.

13. The method according to claim 11, wherein said implanting of said additional impurity is performed such that said additional impurity extends under said permanent spacers.

14. The method according to claim 11, wherein said implanting of said additional impurity is performed such that said additional impurity is implanted to a depth into said surface regions of less than approximately 20 nm from a top surface of said substrate.

15. The method according to claim 11, wherein said laser anneal is performed in such a manner as to recrystallize said surface regions.

16. A method comprising:
forming a gate conductor over a channel region of a device in a substrate;
implanting extension impurities in regions of said substrate not protected by said gate conductor;
forming temporary spacers on sidewalls of said gate conductor;
implanting source and drain impurities in said substrate adjacent said extension impurities;
performing a rapid thermal anneal (RTA) to activate said extension impurities and said source and drain impurities;
removing said temporary spacers;
amorphizing surface regions of said substrate not protected by said gate conductor to create amorphized regions;
performing a laser anneal on said amorphized regions;
forming permanent spacers on said sidewalls of said gate conductor; and
siliciding said surface regions of said substrate not protected by said gate conductor and said permanent spacers, to create silicide regions, such that said silicide regions are formed in said amorphized regions,
wherein said amorphized regions extends toward said channel region further than said silicide regions extend toward said channel region.

17. The method according to claim 16, wherein said implanting of said extension impurities and said amporhizing of said surface regions are performed such that said extension impurities extend from a top surface of said substrate into an interior of said substrate deeper than said amorphized regions extend into said interior of said substrate.

18. The method according to claim 16, wherein said amporhizing of said surface regions is performed such that said amorphized regions extend under said permanent spacers.

19. The method according to claim 16, wherein said amporhizing of said surface regions is performed such that said amorphized regions are formed to a depth into said surface regions of less than approximately 20 nm from a top surface of said substrate.

20. The method according to claim 16, wherein said laser anneal is performed in such a manner as to recrystallize said surface regions.
